(19) United States
(12) Patent Application Publication
(10) Pub. No.: US 2006/0107171 A1
(43) Pub. Date: May 18, 2006

(54) Interleaver and de-interleaver systems

(75) Inventor: Dimitrios Skraparlis, Bristol (GB)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Minato-ku (JP)

(21) Appl. No.: 11/254,773

(22) Filed: Oct. 21, 2005

(30) Foreign Application Priority Data
Nov. 1, 2004 (GB) 0424111.3

(51) Int. Cl. H03M 13/00

(52) U.S. Cl. 714/752

(57) ABSTRACT

This invention relates to bit interleaver and de-interleaver apparatus, methods and processor control code for use in MIMO (Multiple-input multiple-output) communications systems, in particular MIMO systems employing OFDM (orthogonal frequency division multiplexing). We describe a block interleaver for a MIMO communications system, said interleaver being configured to interleave a block of N bits for spatially multiplexed transmission using a plurality of transmit antennas, said interleaver comprising: a matrix memory block configured to store an interleaving matrix, said matrix having a plurality of columns α and a plurality of rows sufficient to store said N bits: an input, coupled to said matrix memory block, to receive data to be interleaved; an output, coupled to said matrix memory block, to output interleaved data; and a controller, coupled to said matrix memory block, to control writing of said received data into said matrix row-by-row, and to control reading of said received data from said matrix column-by-column; and wherein the number of columns α is chosen such that said number of bits N is not an integral multiple of said number of columns α. This results in the last row of the matrix being incompletely filled. We also describe a corresponding de-interleaver and related interleaving and de-interleaving methods.

This invention relates to bit interleaver and de-interleaver apparatus, methods and processor control code for use in MIMO (Multiple-input multiple-output) communications systems, in particular MIMO systems employing OFDM (orthogonal frequency division multiplexing).

A bit interleaver is a hardware structure commonly used with error correction codes such as convolutional codes to counteract the effect of burst errors. Burst errors occur on some physical channels such as fading channels which are typical for both indoor and outdoor wireless environments. In such channels, if the channel is in a deep fade, caused by multipath propagation and/or Doppler spread, a large number of bit errors at the receiver occur in sequence. A bit interleaver takes the bits to be transmitted as input and outputs the same bits in a different sequence. The inverse operation (de-interleaving) is performed at the receiver and re-arranges the bits to the correct order. The effect of interleaver is that the location of bit errors looks random and is distributed over the whole bitstream. In other words, it avoids a local concentration of many errors by dispersing the errors over the whole bitstream. This facilitates error correction and detection and is commonly used in communication systems such as 802.11a.

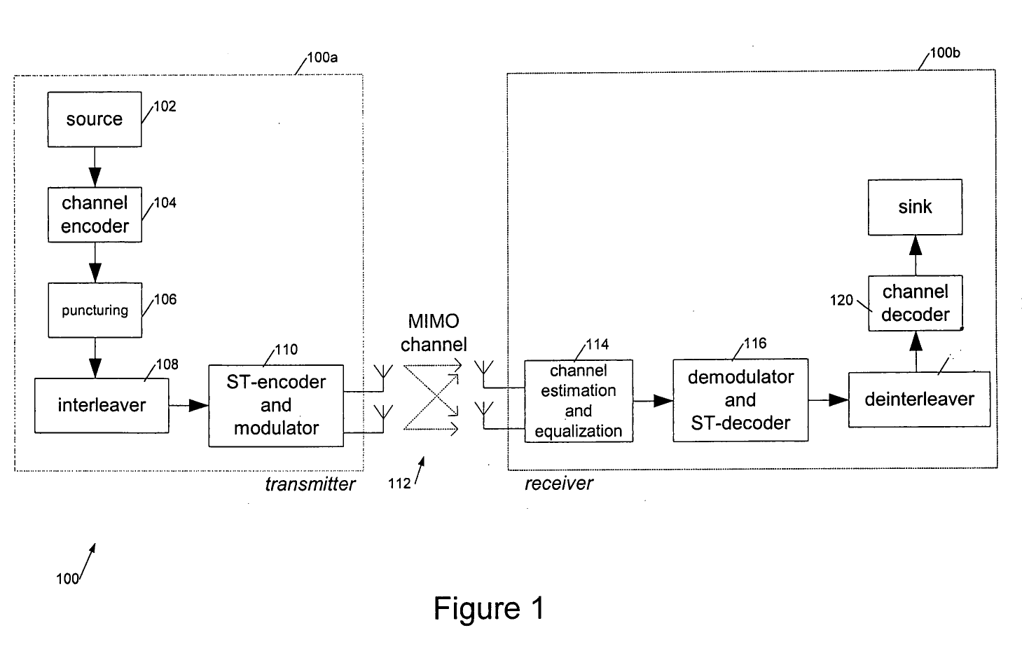

FIG. 1 shows a typical system view of a MIMO communications system 100 comprising a transmitter 100a and receiver 100b, employing error correction and interleaving. A transmitter 100a comprises a source 102 that generates bits, which are then channel encoded 104 and rate-matched using, for example, a convolutional encoder with rate ½ followed by puncturing 106. Puncturing involves removing selected code bits so that they are not transmitted, and is used to reduce the rate of the convolutional encoder to a desired rate, for example ½, ⅔, ¾ of the code rate (as specified in IEEE Std. 802.11a-1999), thus changing the error correction capabilities without changing the overall code structure. An interleaver 108 re-arranges the bit positions of the encoded bits and then the new stream of bits is mapped into space (across antennas), time and frequency (across subcarriers, in the case of OFDM systems) by a ST-encoder (space-time encoder) and modulator 110 and transmitted over the physical MIMO channel 112. The corresponding receiver 100b includes channel estimation and equalisation 114 to estimate and equalise the MIMO channel. For example a training sequence can be transmitted from each transmit antenna in turn, each time listening on all the receive antennas to characterise the channels from that transmit antenna to the receive antennas; some particularly advantageous training sequences are described in the Applicant's UK patent application no. 0222410.3 filed on 26 Sep. 2002 (TRLP034). This is followed by a decoder 116, which performs the inverse process of demodulating and ST-decoding the received transmissions. The resulting bits are then de-interleaved 118 and decoded 120 using, for example, a Viterbi decoder, producing an estimation of the original bits that the transmitter source generated.

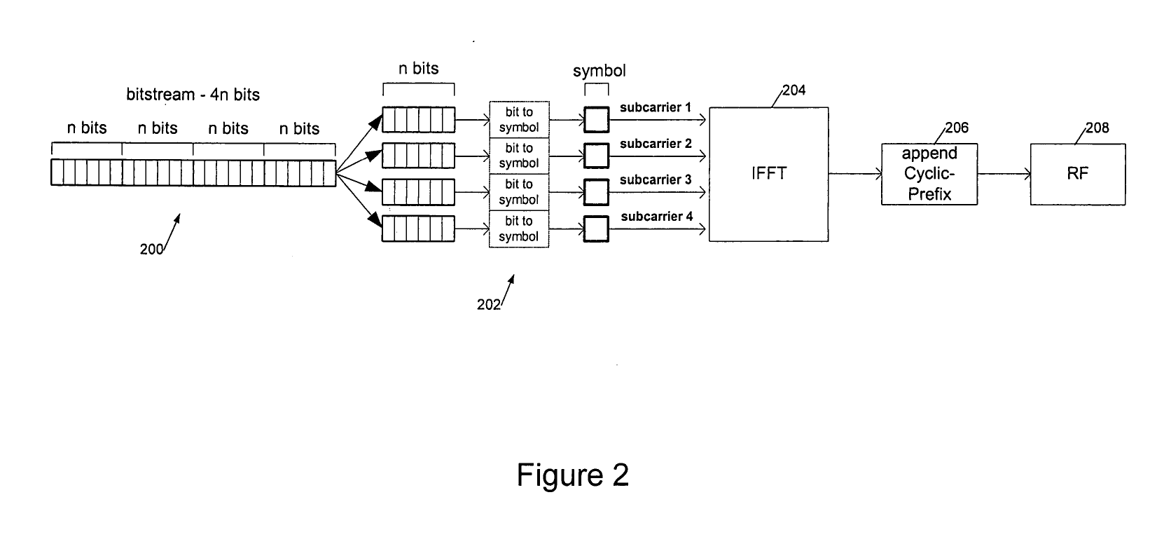

The 802.11a standard uses the OFDM technique, which transmits 52 equally spaced (over frequency) orthogonal subcarriers (48 with 4 pilot subcarriers, out of 64 possible subcarrier slots). FIG. 2 illustrates diagrammatically an example of how data bits are mapped to subcarriers. An input bitstream 200 of 4n bits is divided into four sets of n bits each and then mapped 202 to respective constellation symbols for (in this simplified illustration, four) OFDM subcarriers. The four subcarriers 1-4 are used as inputs to an IFFT block 204 which outputs an OFDM symbol to which is appended a cyclic prefix 206 to mitigate inter-symbol interference due to multipath, prior to rf transmission 208. This process is typical to an OFDM system and is only mentioned here in order to facilitate the description of the invention.

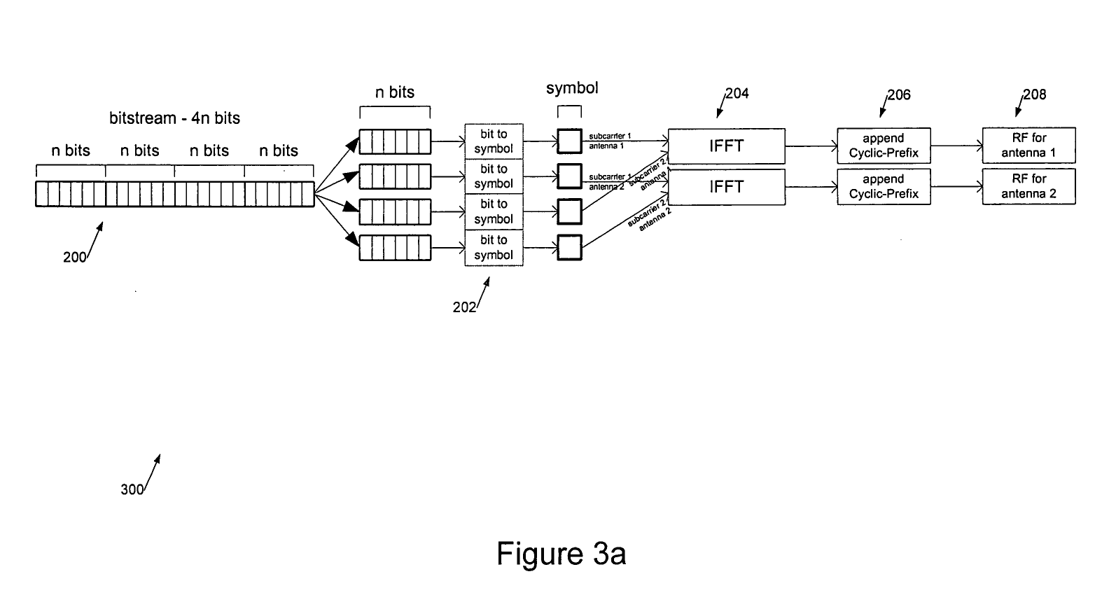

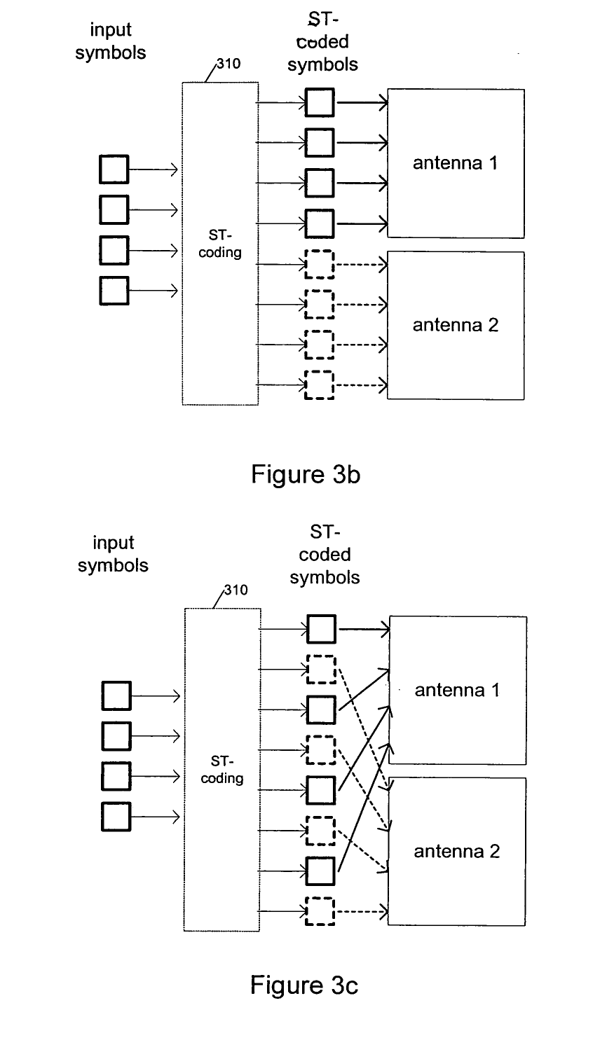

FIG. 3a shows a similar OFDM system 300 employing MIMO, in which like elements to those of FIG. 2 are indicated by like reference numerals. In the MIMO OFDM system 300 the bits are converted to symbols and, in the case of for example two transmit antennas, every second symbol is used as an input to the IFFT block 204 for the corresponding antenna 208 (there is one IFFT block per antenna). In other words, symbols 1,3,5,7, . . . are assigned to antenna 1, while symbols 2,4,6,8, . . . are assigned to antenna 2. FIG. 3c shows a portion of a modified version of the system of FIG. 3a in which an ST-coder 310 is employed to apply ST-coding to the OFDM input symbols prior to transmission.

FIGS. 3a and 3c show MIMO systems that map symbols to antennas in a “multiplexing” fashion. Thus referring to FIG. 3c, after Space-Time coding, it can be seen that the resulting symbols are multiplexed to the transmit antennas. The inverse process is performed at the receiver. This “multiplexing” method, as shown in the simplified examples of FIGS. 3a and 3c, is the preferred method of assigning symbols to antennas for the later described embodiments of the invention. FIG. 3b shows an alternative, “block” method of assigning symbols to antennas in which, for example, the first two symbols are assigned to antenna 1, the second two symbols are assigned to antenna 2, and so forth.

As explained above, the performance of communication systems employing forward error correction (FEC) codes can be improved by bit interleaving, which involves creating a permutation of the coded bit stream so that bits that were adjacent to each other when leaving the encoder are separated during transmission over the channel. It is common to define such a permutation mathematically.

It is helpful for understanding the invention to review the interleaving and de-interleaving processes defined in the IEEE Standard 802.11a, Wireless LAN Medium Access Control (MAC) and Physical Layer (PHY) specifications High-speed Physical Layer in the 5 GHz Band, 1999 (hereby incorporated by reference). The interleaver can be summarised as a two stage interleaver designed to ensure that consecutive bits are mapped to every third OFDM subcarrier (first stage) and also mapped to different bit positions in the constellation (second stage). Other OFDM-based wireless standards such as IEEE802.11g and Hiperlan/2 (ETSI TS 101 475 (BRAN), HIPERLAN TYPE 2, Physical (PHY) Layer, 2001) use the same interleaving scheme.

The first 802.11a interleaver stage comprises a first permutation defined by the rule:
π(i)=(Ncbps/16)(i mod 16)+floor(i/16)
where i=0 . . . Ncbps-1 is the position of the input bit and π(i) is its position after the permutation, and floor(parameter) is the largest integer not exceeding the parameter.

This first stage of the 802.11a interleaver is the so-called classical “LR/TB” block interleaver described in, for example Section 3.2 of “Turbo Coding” by Chris Heegard and Stephen B. Wicker, Kluwer Academic Publishers, 1999. Here LR/TB stands for Left-Right/Top-Bottom, which describes the way the bits are written and read during the operation of the interleaver: bits are read-in as rows of a 2-D matrix and read-out as columns.

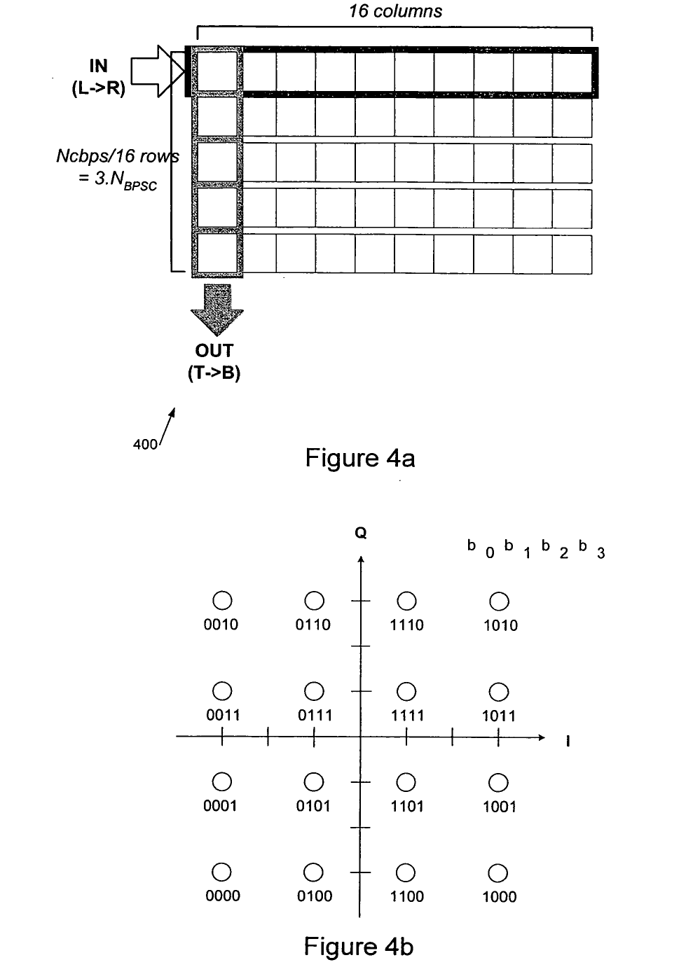

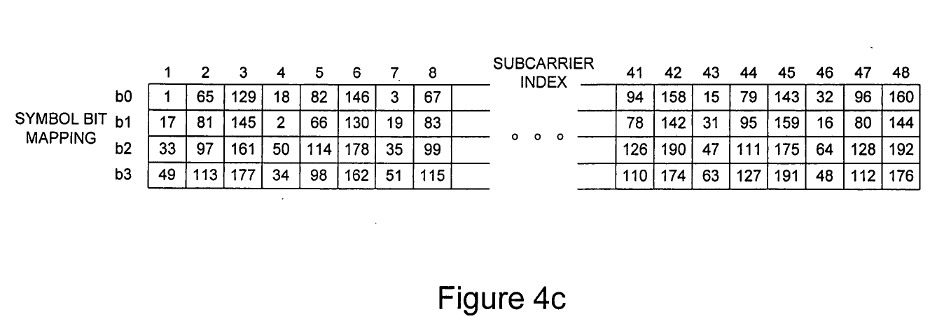

FIG. 4a shows the structure 400 of such a classical Left-Right/Top-Bottom block interleaver. This comprises a 2-D matrix with Ncbps/16 rows and 16 columns where Ncbps is the number of bits per OFDM symbol (equivalent to the value of 4*n in FIGS. 2 and 3) and N_{BPSC} is the number of bits per subcarrier (corresponding to “n” in FIGS. 2 and 3).

This interleaver can be rewritten in mathematical terms:
π(i)=16·i mod (Ncbps-1), i=0 . . . Ncbps-1, π(Ncbps-1)=Ncbps-1
where i is the position of the input bit. This position is multiplied by 16, the result is then divided by (Ncbps-1), and the resulting remainder is the new bit position π(i). This is equivalent to taking every 16^{th} bit and placing them to adjacent positions.

The second 802.11a interleaver stage comprises a second permutation defined by the rule:
π(i)=s*floor(i/s)+(i+Ncbps−floor(16*i/Ncbps)) mod s
where i=0 . . . Ncbps-1 is the position of the input bit and π(i) is its position after the permutation. Here s is dependent on the constellation size—it is 3 for 64-QAM, 2 for 16-QAM, and 1 for QPSK and for BPSK or, more generally, s=max (N_{BPSC}/2; 1).

In this second stage, the bitstream is processed in groups of s bits and a cyclic bit shifting is performed (per group), having a shift step=t mod s bits (t=0 . . . 15, increasing by 1 in every Ncbps/16 bits). This maps bits to constellation bit positions of alternating reliability.

This can be understood by considering the example of FIG. 4b, which shows a graph of the 16 QAM (Quadrature Amplitude Modulation) constellation. In this figure dots plot the 16 symbols with respect to their in-phase (I) and quadrature (Q) components and the symbols are mapped to values between 0000(binary) and 1111 (binary) of a binary number bₒb₁b₂b₃.

In the general case, for a constellation that conveys M bits per symbol, denoted as the vector [bₒ,b₁, . . . , b_{M-1}], the reliability of a bit being successfully received can vary according to its position within the vector and the reliability of each bit position is dependent upon the exact bit-to-symbol mapping. Reliability depends on the Euclidean distance between symbols (as plotted on the graph of quadrature component against in-phase component of FIG. 4b) and whether the symbols represent bit vectors with bits of common value. For example a certain transmitted symbol is in many cases most likely to be wrongly detected as one of its closest neighbouring symbols. If all neighbouring symbols represent the same bit value in a particular bit position then this bit position will be more reliable than if the bit values are different.

In the allocation illustrated in FIG. 4b, the bit mapping results in bits b₀ and b₂ having equal reliability, and bits b₁ and b₃ having equal reliability. The process of distinguishing between b₀=0 and b₀=1 is one of determining whether the in-phase component of the received signal is positive or negative. Similarly, the process of distinguishing between b₂=0 and b₂=1 is one of determining whether the quadrature component of the received signal is positive or negative. On the other hand, the process of determining the value of b₁ or b₃ is based on the amplitude of the in-phase or quadrature components, respectively.

FIG. 4c shows a diagram illustrating bit allocations for an IEEE 802.11a interleaver for a single OFDM symbol with 48 subcarriers in a system using 16 QAM modulation.

It can be seen that adjacent bits are allocated to every third subcarrier and that they alternate between bit positions b₀ and b₁ or between b₂ and b₃. The 802.11a interleaver is designed for a block size equal to the number of coded bits that are conveyed in each OFDM symbol, which can vary since 802.11a systems allow for adaptive modulation and coding.

We next review the IEEE 802.11a de-interleaver.

In de-interleaving at the receiver, the inverse process interleaving is performed. This begins with:
π⁻¹(i)=s*floor(i/s)+(i+floor(16*i/Ncbps)) mod s, i=0 . . . Ncbps-1

This stage is the inverse of the second interleaving stage. Then the inverse of the first interleaving stage is performed:
π⁻¹(i)=16*i−(Ncbps-1)*floor(16*i/Ncbps), i=0 . . . Ncbps-1

This second step is equivalent to implementing a classical “TB/LR” block deinterleaver, where TB/LR stands for Top-Bottom/Left-Right, which describes the way the bits are written and read during the operation of the interleaver. Bits are read-in as columns of a 2-D matrix and read-out as rows (although it will be appreciated that the labelling of rows and columns for the 2D matrix is arbitrary).

The structure of this deinterleaver is the same as the one shown in FIG. 4a, with the only difference of the way the bits are loaded-in and read-out. The interleaving matrix is still a 2-D matrix with Ncbps/16 rows and 16 columns. This enables a single hardware resource for the second stage of the intereleaver to be used for de-interleaving too (only the loading/read-out procedure is different).

An architecture for a block interleaver in which data is written and read word-by-word rather than bit-by-bit is described in Eric Tell and Dake Liu, “A Hardware Architecture for a Multi Mode Block Interleaver”, Proc. of the International Conference on Circuits and Systems for Communications (ICCSC), Moscow, Russia, June 2004.

Interleaving design depends on the application and thus specific designs are desirable for MIMO systems, in particular MIMO OFDM systems employing convolutional coding.

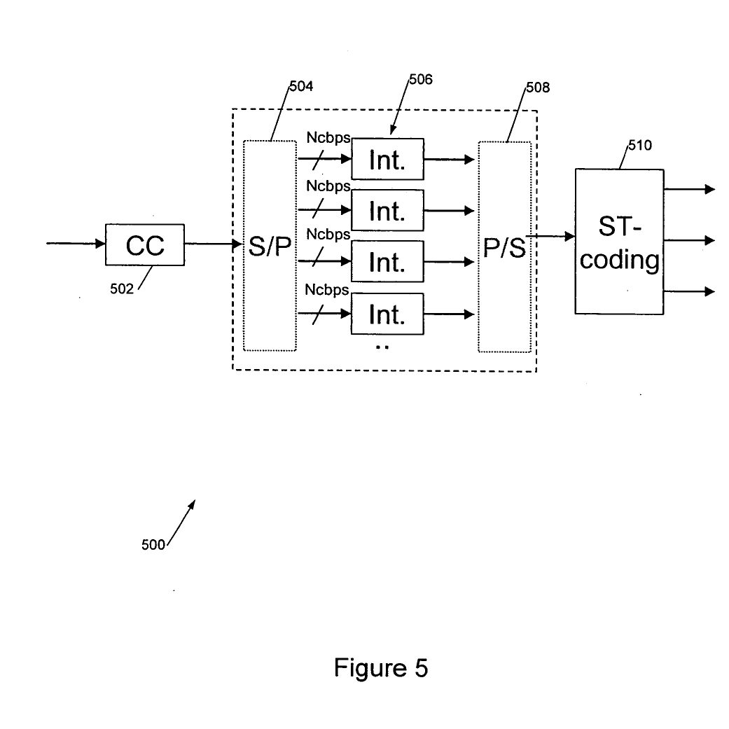

All 802.11a systems are single antenna systems, and therefore the interleaver interleaves bits transmitted over the single antenna. In a case where multiple antennas are employed (MIMO), one can imagine extending the 802.11a interleaver by separating the input stream into a number of streams equal to the number of antennas and operating the 802.11a interleaver on each stream separately; this is illustrated diagrammatically in FIG. 5.

FIG. 5 shows one possible MIMO OFDM interleaving system 500 in which a convolutional coder CC 502 encodes the input bits (and also performs puncturing) and then a Serial to Parallel function 504 splits the bits into blocks of Ncbps bits, which are then each separately interleaved 506 according to the 802.11a interleaver system described above. The resulting blocks of bits are then concatenated back to a single long bit stream by a parallel-to-serial converter 508, and this bit stream is then Space-Time encoded 510 and mapped to antennas according to the “block” method of FIG. 3b and transmitted.

De-interleaving (not shown in FIG. 5) may be performed in similar, but complementary manner: after ST-decoding at the receiver, the bit stream is again grouped into Ncbps blocks of bits, and the de-interleaver operates on each block separately.

However the inventor has simulated the performance of this method and it appears that it does not yield good results (as illustrated later). Improved interleaving methods and apparatus for MIMO systems, and corresponding de-interleaving methods and apparatus, are therefore desirable.

We have previously described a number of improved systems in the Applicant's earlier related UK patent application number no. 0413687.5 filed 18 Jun. 2004. Here we describe further improved architectures and implementation methods suitable for MIMO interleavers and de-interleavers.

According to a first aspect of the present invention there is therefore provided a block interleaver for a MIMO communications system, said interleaver being configured to interleave a block of N bits for spatially multiplexed transmission using a plurality of transmit antennas, said interleaver comprising: a matrix memory block configured to store an interleaving matrix, said matrix having a plurality of columns α and a plurality of rows sufficient to store said N bits: an input, coupled to said matrix memory block, to receive data to be interleaved; an output, coupled to said matrix memory block, to output interleaved data; and a controller, coupled to said matrix memory block, to control writing of said received data into said matrix row-by-row, and to control reading of said received data from said matrix column-by-column; and wherein said number of columns α a and the number of said rows are selected such that when said block of N bits is written into said matrix one row of said matrix is incompletely filled.

In a complementary aspect the invention provides a block interleaver for a MIMO communications system, said interleaver being configured to interleave a block of N bits for spatially multiplexed transmission using a plurality of transmit antennas, said interleaver comprising: a matrix memory block configured to store an interleaving matrix, said matrix having a plurality of columns α and a plurality of rows sufficient to store said N bits: an input, coupled to said matrix memory block, to receive data to be interleaved; an output, coupled to said matrix memory block, to output interleaved data; and a controller, coupled to said matrix memory block, to control writing of said received data into said matrix row-by-row, and to control reading of said received data from said matrix column-by-column; and wherein the number of columns α is chosen such that said number of bits N is not an integral multiple of said number of columns α

Preferably the number of columns and the number of bits N are co-prime. More preferably the number of columns is a prime number (less than N); a value which has been found to be particularly effective is 37, another example of a suitable value is 23.

Preferably the communications system is an OFDM communications system in which transmitted data is space-time encoded across the plurality of transmit antennas. The number of bits N stored in said matrix is then determined by a product of a number of bits per OFDM symbol and the number of symbols encoded across the transmit antennas.

The data may be written into the matrix memory block either bit-by-bit or word-by-word; the data may be read from matrix memory block similarly. The block interleaver may perform all the interleaving of the MIMO communications system or the block interleaver may be used as a replacement for the first stage of the above mentioned 802.11a interleaving system where a two-stage system of this general type is employed, in which case the intra-column second stage permutation may be implemented by reordering the bits on an output data bus of the memory block. In embodiments of the block interleaver the bit (or word) addressing may either be performed by dedicated hardware or by a processor operating in accordance with processor control code.

The invention further provides a transmitter including an interleaver as described above, preferably comprising a convolutional coder, the interleaver being configured to interleave the convolutionally coded data. Preferably the transmitter is an Orthogonal Frequency Division Multiplexing (OFDM) transmitter and preferably, therefore, the interleaver is configured to interleave the block of N bits across frequency, that is across OFDM subcarriers. It will be appreciated that because we are describing a block interleaver for a MIMO communications system there is also generally interleaving across OFDM symbols.

In a complementary aspect the invention also provides a block de-interleaver for a MIMO communication system, said de-interleaver being configured to de-interleave a block of N bits received from a spatially multiplexed transmission, said de-interleaver comprising: a matrix memory block configured to store an interleaving matrix, said matrix having a plurality of columns α and a plurality of rows sufficient to store said N bits; an input, coupled to said matrix memory block, to receive data to be de-interleaved; an output, coupled to said matrix memory block, to output de-interleaved data; and a controller, coupled to said matrix memory block, to control writing of said received data into said matrix column-by-column, and to control reading of said received data from said matrix row-by-row; and wherein the number of columns α is chosen such that said number of bits N is not an integral multiple of said number of columns α.

The invention further provides a block de-interleaver for a MIMO communication system, said de-interleaver being configured to de-interleave a block of N bits received from a spatially multiplexed transmission, said de-interleaver comprising: a matrix memory block configured to store an interleaving matrix, said matrix having a plurality of columns α and a plurality of rows sufficient to store said N bits; an input, coupled to said matrix memory block, to receive data to be de-interleaved; an output, coupled to said matrix memory block, to output de-interleaved data; and a controller, coupled to said matrix memory block, to control writing of said received data into said matrix column-by-column, and to control reading of said received data from said matrix row-by-row; and wherein said number of columns α and the number of said rows are selected such that when said block of N bits is written into said block one row of said matrix is incompletely filled.

The invention further provides a receiver including a de-interleaver as described above, the receiver preferably comprising a convolutional code decoder, the de-interleaver being configured to de-interleave convolutionally coded data prior to convolutional code decoding. Preferably the receiver is configured as an OFDM receiver and preferably therefore the de-interleaver is configured to de-interleave across the OFDM subcarriers. It will be appreciated that, as previously mentioned, because de-interleavers we describe are intended for MIMO communications systems, a de-interleaver will generally de-interleave across OFDM symbols.

The invention further provides a method of interleaving a block of N bits of data for MIMO transmission, the method comprising: writing said N bits of data row-by-row into a matrix memory block as a matrix having a plurality of columns α and a plurality of rows sufficient to store said N bits; and reading said block of N bits from said matrix column-by-column; and wherein the number of columns α is chosen such that said number of bits N is not an integral multiple of said number of columns α

The invention further provides a method of interleaving a block of N bits of data for MIMO transmission, the method comprising: writing said N bits of data row-by-row into a matrix memory block as a matrix having a plurality of columns α and a plurality of rows sufficient to store said N bits; and reading said block of N bits from said matrix column-by-column; and wherein said number of columns α and the number of said rows are selected such that when said block of N bits is written into said matrix one row of said matrix is incompletely filled.

The invention further provides a method of de-interleaving a block of N bits of data received over a MIMO channel, the method comprising: writing said N bits column-by-column into a matrix memory block as a matrix having a plurality of columns α and a plurality of rows sufficient to store said N bits; and reading said block of N bits from said matrix row-by-row; and wherein the number of columns α is chosen such that said number of bits N is not an integral multiple of said number of columns α.

The invention further provides a method of de-interleaving a block of N bits of data received over a MIMO channel, the method comprising: writing said N bits column-by-column into a matrix memory block as a matrix having a plurality of columns α and a plurality of rows sufficient to store said N bits; and reading said block of N bits from said matrix row-by-row; and wherein said number of columns α and the number of said rows are selected such that when said block of N bits is written into said matrix one row of said matrix is incompletely filled.

The above described interleavers and de-interleavers and corresponding methods may conveniently be implemented using a data processor under control of suitable processor control code.

Thus in a further aspect the invention provides processor control code to implement the above described interleavers, de-interleavers and corresponding methods, preferably provided on a data carrier such as a disk, CD- or DVD-ROM, programmed memory such as read-only memory or EEPROM (firmware), or on a data carrier such as an optical or electrical signal carrier. Embodiments of the invention may also be implemented on an ASIC or FPGA. Thus the processor control code may comprise code in a conventional programming language such as C, or microcode, or code for setting up for controlling an ASIC or PFGA, or code for a hardware description language such as Verilog(™), VHDL (very high speed integrated circuit hardware description language) or SystemC. As the skilled person will appreciate such code and/or data may be distributed between plurality of coupled components in communication with one another, for example on a network.

A communications system may be provided comprising a transmitter apparatus in accordance with any aspect of the invention and an appropriately configured receiver.

The invention further provides a MIMO OFDM signal comprising data interleaved by the method or apparatus described above.

These and other aspects, preferred features and advantages of the invention will now be further described, by way of example only, with reference to the accompanying drawings, in which:

FIG. 1 shows a typical MIMO communications system employing error correction and interleaving;

FIG. 2 illustrates diagrammatically an example of how data bits may be mapped to subcarriers in a conventional single transmit antenna OFDM communications system;

FIGS. 3a to 3c show, respectively, first multiplexing, block, and second multiplexing arrangements for the mapping of symbols to antennas in MIMO OFDM communications systems;

FIGS. 4a to 4c show, respectively, a known Left-Right/Top-Bottom block interleaver, the 16 QAM constellation, and a diagram illustrating bit allocations for an IEEE 802.11a interleaver for a single OFDM symbol;

FIG. 5 shows one example of a MIMO OFDM interleaving system;

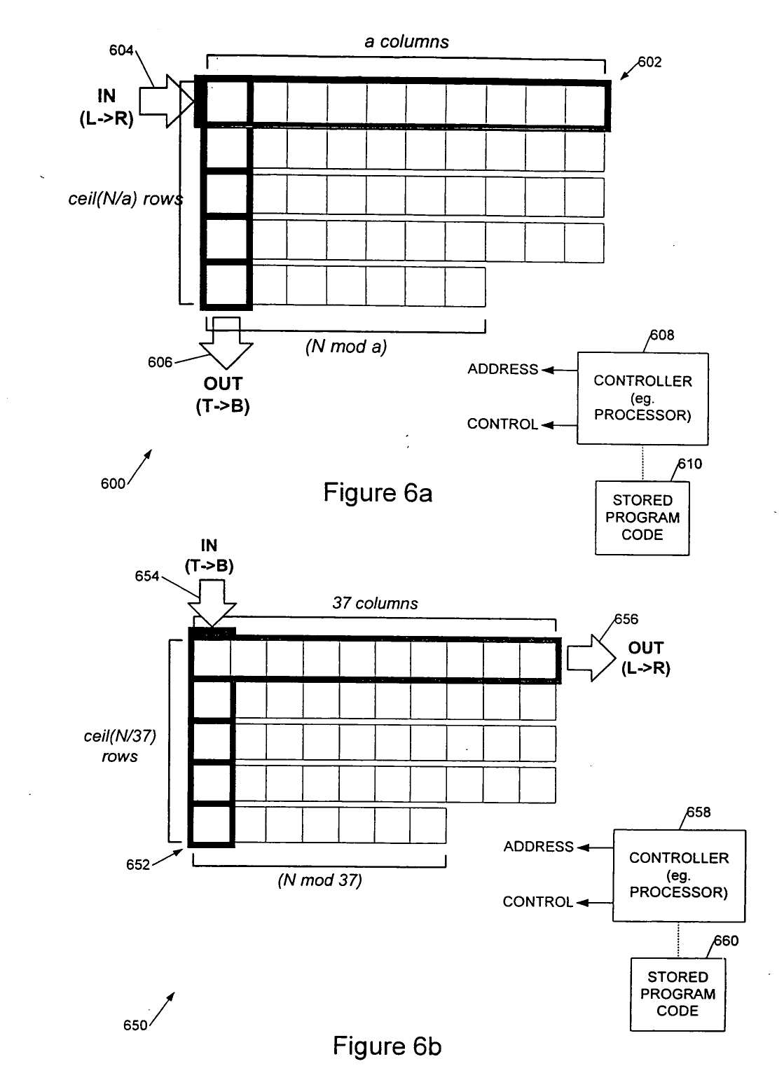

FIGS. 6a and 6b show structures of, respectively, an interleaver and a de-interleaver according to embodiments of the present invention;

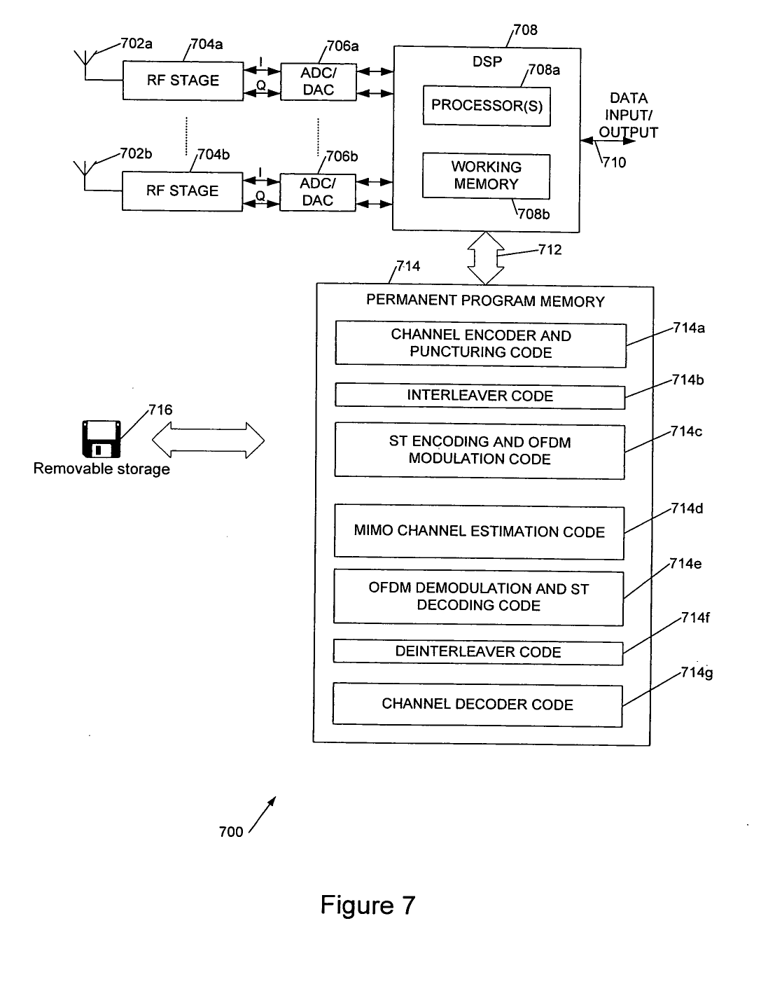

FIG. 7 shows a transceiver 800 incorporating an interleaver and de-interleaver according to embodiments of the present invention; and

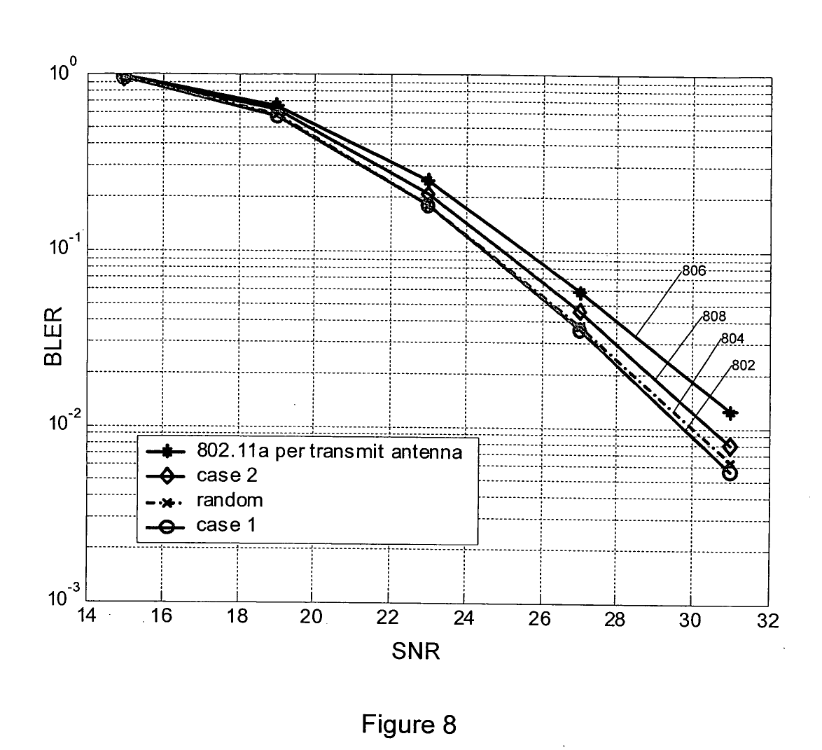

FIG. 8 shows curves of Block Error Rate (BLER) against signal to noise ratio per receive antenna (SNR) for MIMO communications systems with different interleavers/de-interleavers, including an interleaver and de-interleaver according to an embodiment of the present invention.

The interleaver process is executed on receipt of a block of N data bits, preferably so that adjacent coded bits are mapped in such a way that they fall on different, and usually widely separated, sub-carriers, preferably onto different bit positions within a symbol, and preferably onto different positions within the encoded space-time block so that they are transmitted from different antennas. A complementary de-interleaving operation employs knowledge of the bit index permutation applied by the interleaver, in order to conduct the reverse permutation of the bit ordering.

We now describe how such a process can be implemented and describe an improved architecture which can be used for a range of interleaving and deinterleaving schemes.

Referring to FIG. 6a, this shows the structure of an interleaver 600 which comprises a 2D matrix 602, which may be conveniently implemented in a matrix memory block, the matrix having a number of columns α (in the Figure “a” is used) and a number of rows M=ceil(N/α) rows, where ceil(parameter) is the smallest integer exceeding the parameter (i.e. the “ceiling”). For the purposes of illustration a value of α=37 is employed.

The matrix has a data input 604, to receive data bits for interleaving, and a data output for reading interleaved data bits from the matrix memory block. There is also an associated controller 608 to provide address and control signals (such as read/write and data strobes) to the matrix memory block to control the writing of data into the matrix and the reading of data from the memory to perform the interleaving function (or, in similar de-interleaver, a de-interleaving function). Controller 608 may be implemented using an ASIC or FPGA, for example by means of a state machine, or by means of a processor under control of stored program code 610.

In operation input bits are loaded from left to right into the 37 (in this example) columns of interleaving matrix 602. However, as can be seen from FIG. 6a, the last row is not completely filled due to the choice of α, in this case the prime number 37. The bits written into matrix 602 are then read-out from top to bottom, in a fashion similar to the first stage of the 802.11a interleaver. However the last (N mod α) columns store only M-1 bits or, equivalently, the last row only has N mod α bits.

Where, for example, “multiplexed” mapping of ST-encoded symbols to antennas is employed, as shown in FIGS. 3a and 3c, this operation can map consecutive input bits onto different sub-carriers, symbol bit positions, and transmit antennas.

In an OFDM system the number of data bits N per interleaved block may be determined by calculating the product of Ncbps (the number of bits per OFDM symbol) and the number of antennas, for example, 48×4×2 for 48 sub-carriers, 16 QAM modulation, and 2 transmit antennas. More generally the number of data bits N is determined by the product of Ncbps and the number of input symbols to one space-time block (equal to the number of transmit antennas if the space-time encoder is set for spatial multiplexing transmissions but if it is set for, say, Alamouti encoding, equal to 2)—depending upon the space-time encoder employed the number of input symbols to ore space-time block does not have to be equal to the number of transmit antennas.

The value of α is in the range 1≦α≦N, and is preferably chosen such that for a given value (or set of values) of N the bit permutation resulting from the interleaver places consecutive input bits on different sub-carriers, on different symbol bit positions, and on different symbols in the space-time encoded block. The number of columns α and N should not share a common factor, and α and N may be co-prime (the requirement for two integers to be co-prime is that they share no common positive factors except 1). Since N can often take several values, it is useful to pick α to be a prime number that is not a divisor of any of the values that N will take. Examples of suitable values of α that could be chosen are 23 or 37; the latter has been found to be particularly effective. However, it will be appreciated that many other values could be chosen.

FIG. 6b shows the structure of a de-interleaver 650 which, as can be seen, is similar to that of the interleaver, comprising a matrix memory storing a matrix of data bits 652, an input 654 to the matrix, an output 656 from the matrix and a controller 658, optionally under the control of stored code 660. The de-interleaver operates in a complementary manner to the interleaver and thus a de-interleaving procedure is followed to load-in the bits received from the Space-Time decoder and read-out the bits. More particularly, instead of a Left-Right/Top-Bottom write/read procedure the bits are written in from Top to Bottom, column after column and read-out from Left to Right, row after row. Thus, the de-interleaving matrix 652 has the same dimensions as the interleaving matrix 602 and only the loading/reading procedure need be different. For this reason a de-interleaver and an interleaver may conveniently be implemented together, using shared hardware resources, if desired.

FIG. 7 shows a transceiver 700 incorporating an interleaver and de-interleaver structured as described above.

Transceiver 700 comprises a plurality of transceive antennas 702a,b (of which two are shown in the illustrated embodiment) each coupled to a respective transmit/receive RF stage 704a,b (duplexers not shown for clarity of illustration), and thence to respective analogue-to-digital/digital-to-analogue converters 706a,b and to a digital signal processor (DSP) 708. DSP 708 will typically include one or more processors 708a and some working memory 708b. The DSP 708 has a data input/output 710 and an address, data and control bus 712 to couple the DSP to permanent program memory 714 such as flash RAM or ROM. Permanent program memory 714 stores code and optionally data structures or data structure definitions for DSP 708.

As illustrated program memory 714 includes channel encoder and puncturing code 714a, interleaver code 714b, ST encoding and OFDM modulation code 714c, MIMO channel estimation code 714d, OFDM demodulation and ST decoding code 714e, deinterleaver code 714f, and channel decoder code 714g. Optionally the code in permanent program memory 714 may be provided on a carrier such as an optical or electrical signal carrier or, as illustrated in FIG. 7, a disk 716.

The data input/output 710 of DSP 708 couples to further data processing elements of receiver 700 (not shown in FIG. 7) as desired. These may comprise, for example, a baseband data processor for implementing higher level protocols.

The transmitter rf output stage and receiver front-end will generally be implemented in hardware whilst the receiver processing will usually be implemented at least partially in software, although one or more ASICs and/or FPGAs may also be employed. The skilled person will recognise that all the functions of the receiver could be performed in hardware and that the exact point at which the signal is digitised in a software radio will generally depend upon a cost/complexity/power consumption trade-off.

FIG. 8 shows curves of Block Error Rate (BLER) against signal to noise ratio per receive antenna (SNR) for a MIMO communications system, comparing four different types of interleaver (and de-interleaver): an interleaver as described above according to an embodiment of the present invention with α=37 (curve 802), a random interleaver (curve 804), an interleaver as shown in FIG. 5 with one 802.11a interleaver applied separately to a bit stream for each antenna (curve 806), and a further alternative interleaving scheme (curve 808) as described in the Applicant's co-pending UK patent application no ______, entitled “Interleaver and de-interleaver systems” and filed on the same day as this application.

The curves of FIG. 8 were determined show the probability of a block error in a block of 2298 information bits before convolutional encoding and space-time encoding. The simulation parameters were as follows:
3×3 MIMO system (3 transmit and 3 receive antennas)
OFDM transmission of 48 subcarriers
a ST-code as described in UK patent application no. 0410644.9 filed by the present Applicant on 12 May 2004 (TRLP107)
64 QAM modulation
convolutional code of ⅔ coderate, as specified in the 802.11a standard
a 802.11n MIMO non-line of sight (NLOS) channel model (model ‘B’), as specified in the draft standard 802.11n. This is a multipath correlated MIMO channel, simulating real MIMO physical channel conditions.

All interleavers assume the “multiplexing” mapping from ST-coded symbols to antennas shown in FIGS. 3a and 3c.

A random interleaver is a structure which performs random permutations of the input bits. The permutations are different for every block transmitted, that is the permutations generated during each block of transmitted bits changes with every block and is pseudo-random (based on random numbers generated from a pseudo-random source such as a computer program). The random interleaver is not a realistic hardware resource but is a reference benchmark for research on interleavers, because of its performance: Interleavers that challenge the random interleaver in performance, deliver a performance that is close to optimal.

It can be seen that the interleaver of curve 802 has a performance close to that of a random interleaver, as does the interleaver of curve 808. It can also be seen that the interleavers of both curves 802 and 808 outperform the 802.11a interleaver by 1.5 to 2 dB, thereby demonstrating the improved performance of interleavers embodying aspects of the present invention.

The above described interleaving and de-interleaving systems can be incorporated into the transmitter 100a and receiver 100b of FIG. 1 respectively. It will be appreciated that in many circumstances, a wireless communications device will be provided with the facilities of a transmitter and a receiver in combination but, for this example, the devices have been illustrated as one way communications devices for reasons of clarity.

It will be appreciated that a general purpose transmitter or general purpose receiver can be configured to implement an embodiment of the present invention by the introduction of suitable software to be executed by a computer apparatus. To that end, an aspect of the invention comprises a product, storing computer executable instructions in a computer readable form, which in use causes a computer with suitably configurable hardware components, to operate substantially in accordance with the invention as exemplified by the described-embodiment. The product may comprise a storage medium such as an optical disk, a magnetic storage medium or a storage medium of any other technology, an active component such as a removable ROM unit or other memory device such as a memory card, or may comprise a signal such as could be received in a download, the signal bearing data defining such computer readable instructions as to establish a computer executable program product. The product may also comprise an application specific integrated circuit which, when installed in a suitably configured general purpose device, renders the resultant system operable in accordance with any of the aspects of the invention exemplified by the described embodiments.

Embodiments of the invention provide low complexity interleavers and have application in wireless local area network (WLAN) communications systems such as IEEE802.11n, and in other MIMO communications systems, in particular those using convolutional channel coding.

The scope of protection claimed in the appended claims is to be determined on the basis of the description, with reference to the accompanying drawings, but not to the extent that features of the specific embodiments of the invention are to be construed as limitations on the scope of features of the claims.

1. A block interleaver for a MIMO communications system, said interleaver being configured to interleave a block of N bits for spatially multiplexed transmission using a plurality of transmit antennas, said interleaver comprising:
a matrix memory block configured to store an interleaving matrix, said matrix having a plurality of columns α and a plurality of rows sufficient to store said N bits:
an input, coupled to said matrix memory block, to receive data to be interleaved;
an output, coupled to said matrix memory block, to output interleaved data; and
a controller, coupled to said matrix memory block, to control writing of said received data into said matrix row-by-row, and to control reading of said received data from said matrix column-by-column; and
wherein said number of columns α and the number of said rows are selected such that when said block of N bits is written into said matrix one row of said matrix is incompletely filled.

2. A block interleaver for a MIMO OFDM communications system, said interleaver being configured to interleave a block of N bits for spatially multiplexed transmission using a plurality of transmit antennas, said interleaver comprising:
a matrix memory block configured to store an interleaving matrix, said matrix having a plurality of columns α and a plurality of rows sufficient to store said N bits:
an input, coupled to said matrix memory block, to receive data to be interleaved;
an output, coupled to said matrix memory block, to output interleaved data; and
a controller, coupled to said matrix memory block, to control writing of said received data into said matrix row-by-row, and to control reading of said received data from said matrix column-by-column; and
wherein said number of columns α is chosen such that said number of bits N is not an integral multiple of said number of columns α.

3. A block interleaver as claimed in claim 2 wherein said number of said columns α and said number of bits N are co-prime.

4. A block interleaver as claimed in claim 1, 2 or 3 wherein said number of columns α is a prime number, in particular 37.

5. A transmitter including the interleaver of claim 1, for transmitting using said plurality of transmit antennas, wherein said interleaver is configured to interleave said block of N bits across space.

6. A transmitter as claimed in claim 5 further comprising a convolutional coder, and wherein said interleaver is configured to interleave convolutionally coded data for transmission.

7. A transmitter as claimed in claim 5 configured as an OFDM transmitter, having a plurality of subcarriers, and wherein said interleaver is configured to interleave said block of N bits across said subcarriers.

8. A block interleaver as claimed in claim 2, wherein said number of columns α is a prime number, in particular 37.

9. A transmitter including the interleaver of claim 2, for transmitting using said plurality of transmit antennas, wherein said interleaver is configured to interleave said block of N bits across space.

10. A block de-interleaver for a MIMO communication system, said de-interleaver being configured to de-interleave a block of N bits received from a spatially multiplexed transmission, said de-interleaver comprising:
a matrix memory block configured to store an interleaving matrix, said matrix having a plurality of columns α and a plurality of rows sufficient to store said N bits;
an input, coupled to said matrix memory block, to receive data to be de-interleaved;
an output, coupled to said matrix memory block, to output de-interleaved data; and
a controller, coupled to said matrix memory block, to control writing of said received data into said matrix column-by-column, and to control reading of said received data from said matrix row-by-row; and
wherein said number of columns α and the number of said rows are selected such that when said block of N bits is written into said block one row of said matrix is incompletely filled.

11. A block de-interleaver for a MIMO communication system, said de-interleaver being configured to de-interleave a block of N bits received from a spatially multiplexed transmission, said de-interleaver comprising:
a matrix memory block configured to store an interleaving matrix, said matrix having a plurality of columns α and a plurality of rows sufficient to store said N bits;
an input, coupled to said matrix memory block, to receive data to be de-interleaved;
an output, coupled to said matrix memory block, to output de-interleaved data; and
a controller, coupled to said matrix memory block, to control writing of said received data into said matrix column-by-column, and to control reading of said received data from said matrix row-by-row; and
wherein said number of columns α is chosen such that said number of bits N is not an integral multiple of said number of columns α.

12. A block de-interleaver as claimed in claim 11 wherein said number of said columns α and said number of bits N are co-prime.

13. A block de-interleaver as claimed in claim 10, wherein said number of columns α is a prime number, in particular 37.

14. A receiver including the de-interleaver of claim 10, wherein said de-interleaver is configured to de-interleave said block of N bits across space.

15. A receiver as claimed in claim 14 further comprising a convolutional code decoder, and wherein said de-interleaver is configured to de-interleave convolutionally coded data prior to convolutional code decoding.

16. A receiver as claimed in claim 13 configured as an OFDM receiver having a plurality of subcarriers, and wherein said de-interleaver is configured to de-interleave said block of N bits across said subcarriers.

17. A block de-interleaver as claimed in claim 11, wherein said number of columns α is a prime number, in particular 37.

18. A receiver including the de-interleaver of claim 12, wherein said de-interleaver is configured to de-interleave said block of N bits across space.

19. A method of interleaving a block of N bits of data for MIMO transmission, the method comprising:
writing said N bits of data row-by-row into a matrix memory block as a matrix having a plurality of columns α and a plurality of rows sufficient to store said N bits; and
reading said block of N bits from said matrix column-by-column; and
wherein said number of columns α is chosen such that said number of bits N is not an integral multiple of said number of columns α.

20. A method of interleaving a block of N bits of data for MIMO transmission, the method comprising:
writing said N bits of data row-by-row into a matrix memory block as a matrix having a plurality of columns α and a plurality of rows sufficient to store said N bits; and
reading said block of N bits from said matrix column-by-column; and
wherein said number of columns α and the number of said rows are selected such that when said block of N bits is written into said matrix one row of said matrix is incompletely filled.

21. A method of de-interleaving a block of N bits of data received over a MIMO channel, the method comprising:
writing said N bits column-by-column into a matrix memory block as a matrix having a plurality of columns α and a plurality of rows sufficient to store said N bits; and
reading said block of N bits from said matrix row-by-row; and
wherein said number of columns α is chosen such that said number of bits N is not an integral multiple of said number of columns α.

22. A method of de-interleaving a block of N bits of data received over a MIMO channel, the method comprising:
writing said N bits column-by-column into a matrix memory block as a matrix having a plurality of columns α and a plurality of rows sufficient to store said N bits; and
reading said block of N bits from said matrix row-by-row; and
wherein said number of columns α and the number of said rows are selected such that when said block of N bits is written into said matrix one row of said matrix is incompletely filled.

23. A computer program product comprising a computer usable medium having a computer readable code means embodied in said medium for interleaving a block of N bits of data for MIMO transmission, the computer readable code means being for causing the computer to implement the method of claim 19 or claim 20.

24. A computer program product comprising a computer usable medium having a computer readable code means embodied in said medium for deinterleaving a block of N bits of data for MIMO transmission, the computer readable code means being for causing the computer to implement the method of claim 21 or claim 22.

25. A MIMO OFDM signal comprising data interleaved by the interleaver of any one of claims 1 to 4.

26. A MIMO OFDM signal comprising data interleaved by the transmitter of any one of claims 5 to 7.

27. A MIMO OFDM signal comprising data interleaved by the method of claim 19 or 20.
